(19) United States
(12) Patent Application Publication
(10) Pub. No.: US 2001/0023153 A1
(43) Pub. Date: Sep. 20, 2001

(54) Process for the production of a position sensor and position sensor

(75) Inventors: Josef Mayer, Koengen (DE); Juergen Schiller, Reutlingen (DE)

Correspondence Address: LAW OFFICE OF BARRY R LIPSITZ, 755 MAIN STREET, MONROE, CT, 06468, US

(73) Assignee: Balluff GmbH, Neuhausen (DE)

(21) Appl. No.: 09/812,112

(22) Filed: Mar. 15, 2001

(30) Foreign Application Priority Data
Mar. 17, 2000 (DE) 100 13 218.9

(51) Int. Cl. H05K 1/00

(52) U.S. Cl. 439/736; 439/76.1

(57) ABSTRACT

In order to make a process available for the production of a position sensor comprising a housing, in the housing interior of which an electrical circuit arranged on a carrier is seated, which can be carried out with less time expended and inexpensively it is suggested that the carrier be connected to an electrical connection element to form a carrier-connection element combination, the carrier-connection element combination be introduced into the housing closed at a measuring end from the rear end located opposite the measuring end, the space around the carrier-connection element combination in the interior of the housing be filled with a molding compound up to a specific level and a cap be connected to the rear end of the housing, connections of the connection element being guided through this cap.

### BACKGROUND OF THE INVENTION

1. Field of the Invention

The invention relates to a process for the production of a position sensor with a housing, in the housing interior of which an electrical circuit arranged on a carrier is seated.

Furthermore, the invention relates to a position sensor comprising a housing for accommodating an electrical circuit arranged on a carrier in a housing interior and an electrical connection element.

Position sensors of this type, such as, for example, inductive proximity switches, are also used in “difficult” environmental conditions, such as, for example, in a machine tool where they can be subjected to coolant, lubricant, machining chippings and the like. When such fluids or materials pass into the housing and reach the circuit, the operability of a position sensor may be impaired by this or it may even fail completely.

2. Discussion of the Prior Art

It is therefore known, for example, from WO 82/01630 or DE 195 04 608 A1 to provide the circuit with a sheathing consisting of a molding compound, such as a casting resin, in order to seal the circuit hermetically. As a result, the production of a position sensor is, however, complicated and expensive.

### SUMMARY OF THE INVENTION

The object underlying the invention is therefore to make a process available for the production of a position sensor specified at the outset which allows a production which is less complicated and thus quick and inexpensive.

This object is accomplished in accordance with the invention, in the process specified at the outset, in that the following process steps are provided:

The carrier is connected to an electrical connection element to form a carrier-connection element combination;

the carrier-connection element combination is introduced into the housing closed at a measuring end from a rear end located opposite the measuring end;

the space around the carrier-connection element combination in the interior of the housing is filled with a molding compound up to a specific level and

a cap is connected to the rear end of the housing, the connections of the connection element being guided through this cap.

The inventive process offers a series of different advantages: Not only is the carrier and with it the circuit fixed in the interior of the housing as a result of the molding compound but also a connection element for closing the interior of the housing at the measuring end and also the cap in relation to the housing. No further steps need therefore be taken to fix the connection of the carrier with, for example, the closure element at the measuring end; the molding compound serves not only for the complete encasing of the circuit but also for fixing the components of the position sensor on the housing.

As a result of the fact that the carrier-connection element combination is introduced into the housing from the rear end thereof and subsequently molding compound is cast into it, a relatively large opening space is available for the introduction of the carrier as well as for pouring in the molding compound and so the carrier can be introduced quickly and without any problem and the filling procedure may be carried out quickly and concertedly since molding compound need not be pressed in, in particular, via narrow channels. As a result, a homogeneous distribution of the molding compound may be achieved whilst continuing to avoid air pockets. As a result, a high dielectric strength of the position sensor produced according to the invention is ensured and so this has a high safety class.

The carrier-connection element combination may be fixed in the housing due to the subsequent placement of the cap, namely, in particular, transversely to a longitudinal direction of the housing, wherein this fixing is brought about automatically with the connection to the cap. Since the connection element is already connected to the carrier element, the switch is finished once the cap has been placed in position and the molding compound hardened. In particular, the connection element does not have to be connected to the carrier in addition once the cap is already in place.

Since the carrier is connected to the connection element in a mechanically stable manner, the cap may be used accordingly for a centering and fixing of the carrier via the carrier-connection element combination. As a result, a homogeneous distribution of the molding compound is again ensured and thus a high dielectric strength.

The metal housing itself may be designed in a cost-saving manner since, in particular, no tapering to form a receiving means or for the fixing of a connection element need be provided since this task is attributed to the cap.

Due to the molding compound being poured in from the rear end, a high safety class for the position sensor can also be achieved since a defined air path for preventing any breakdowns can be made available in a controlled manner, namely via the control of the amount of molding compound poured in and thus the level of the molding compound. By arranging a shrinkage tube to the air path, the dielectric strength may also be ensured with respect to the space free from molding compound.

In this respect, the carrier-connection element combination is advantageously arranged in the housing at an angle to a longitudinal direction when molding compound is poured in. As a result, a large opening angle is available for the filling with the molding compound and so this can be poured in more quickly and more concertedly. The carrier-connection element combination is then leaned, in particular, against an inner wall of the housing when molding compound is poured in. Once the specified filling level is reached, the carrier-connection element combination is aligned again and the cap can then be placed in position. In this way, a quick filling with the filling compound effecting a hermetic sealing of the circuit can be achieved.

The cited object is also accomplished in accordance with the invention, in the process specified at the outset, in that the steps:

the carrier is connected to an electrical connection element to form a carrier-connection element combination;

a molding compound is poured into the housing interior of the housing closed at a measuring end up to a specific level:

the carrier-connection element combination is pushed into the housing interior with the molding compound and

a cap is connected to the rear end of the housing, the connections of the connection element being guided through this cap

are carried out one after the other.

This inventive process differs from the process described above essentially due to the fact that the molding compound is first poured into an “empty” housing interior and only afterwards is the carrier-connection element combination pushed in. This has the advantage that the molding compound can easily be poured in since no components are in the way of the filling procedure.

As for the rest, this process has the advantages already specified above.

The connection element is favorably connected rigidly to the carrier and, in particular, in a mechanically secure manner. As a result, the carrier-connection element combination may be aligned via the connection element. This is advantageous because access is easiest to the connection element since this provides the connection to the surroundings. The cap is pushed onto the connection element, in particular, with an opening. The connection element is then seated in this opening at least partially and the carrier-connection element combination is, altogether, aligned and centered via the cap which is, on the other hand, connected to the housing.

It is favorable when a plurality of contact pins of the connection element are connected to the carrier in order to thus provide for a secure connection between connection element and carrier. In this respect, it is particularly advantageous when the connection element is soldered to the carrier. As a result, a rigid and mechanically secure connection is ensured between carrier and connection element for forming the carrier-connection element combination.

To simplify the production of the position switch it is advantageous when a cup-shaped insert is provided at the measuring end for closing the housing and this insert is pushed into the housing in the direction of the rear end from the measuring end. A closure element at the measuring end should not normally be manufactured from a metal since, otherwise, the results of measurement themselves could be influenced. The closure element cannot, therefore, be formed in one piece with the housing but rather it must be connected to the housing afterwards. Due to the design as a cup-shaped insert, the molding compound itself may then be used to provide for a good connection to the housing (in the housing interior) after insertion of the insert. Moreover, such a cup-shaped insert may be pushed into the housing in a simple manner. An additional, electrical insulation between housing and circuit is also brought about due to such an insert and thus the dielectric strength is increased considerably.

In this respect it is favorable when the insert is held on the housing in a force-locking manner after its insertion. No further measures need then be taken during the insertion of the carrier-connection element combination and/or the pouring of the molding compound into the housing interior in order to clamp the insert with the housing so that this closure element is not detached from the housing due to any possible force acting during the insertion/filling; on the contrary, the corresponding design of the insert sees to it that this is not detached from the housing during the production of the position switch.

In addition, it is favorable when the carrier-connection element combination is placed onto a closure element forming the closed measuring end when molding compound is poured in. It is guaranteed as a result that a corresponding sensor and, in particular, a coil is located at the front measuring end.

In order to facilitate filling, the housing is favorably oriented in its longitudinal direction essentially parallel to the direction of gravity during the introduction of the carrier-connection element combination and/or the filling with the molding compound. As a result, it can also be ensured that essentially the entire free space in the housing interior is filled with molding compound.

It is favorable when the amount of molding compound poured into the housing is controlled. As a result, it is possible for filling compound to be introduced into the housing interior up to a specific level in order to, for example, prevent too much molding compound being poured in or not enough molding compound being poured in.

It is favorable when, during the connection of the cap with the housing, the carrier-connection element combination is aligned in longitudinal direction of the housing. As a result, it is possible to avoid the carrier-connection element combination being moved to too great an extent in the molding compound not yet hardened which, in certain circumstances, can lead to air pockets and a quick coupling of the cap to the housing is brought about. For this purpose, the carrier-connection element combination is, in particular, aligned essentially collinear to the longitudinal axis of the housing during the connection of the cap with the housing.

A good connection of the cap with the housing may be achieved when the cap is pushed into the housing. As a result, it is also possible, with a hardened molding compound, for this to fix the cap against the housing since the molding compound can also pass between a space of the housing interior and the cap and is located between the carrier and the cap. When the cap is pushed into the molding compound which is not yet hardened, molding compound is displaced accordingly via buoyancy forces and care is taken that this fills all the spaces to a very large extent. As a result of the inserted cap, which insulates the housing from the circuit, the dielectric strength is also increased.

The cap is favorably pushed into the housing as far as a stop defined on the cap. As a result, when a corresponding amount of molding compound is poured in it is also ensured that the entire circuit is essentially encased by hardened molding compound and the molding compound is present in the housing interior as far as a defined end.

It is particularly advantageous when the cap is pushed into the housing prior to hardening of the molding compound. As a result, the molding compound can be used, after hardening thereof, to fix the cap on the housing and thus also to seal the housing interior in relation to the surroundings in the direction of the cap.

In a variation of one embodiment it is provided for the cap to be positioned on the carrier-connection element combination prior to insertion of the carrier-connection element combination. The cap and the carrier-connection element combination are then pushed as a whole into the housing interior which has been filled accordingly with molding compound beforehand. The carrier may be positioned and fixed in the housing interior in the molding compound, in particular, with the step of connecting the cap with the housing. The carrier-connection element combination is then favorably pushed into the housing with the cap positioned, wherein this housing is filled with molding compound.

It is particularly advantageous when the cap is provided with a fixing means and the connection element with a fixing means adapted thereto. This may, for example, be a tongue on the cap and a notch in the connection element which is adapted to this tongue. As a result, a good connection is provided between the cap and the connection element and thus between the cap and the carrier-connection element combination.

Care must then be taken that during the connection of the cap with the housing the cap and the carrier-connection element combination are oriented relative to one another such that the respective fixing means can engage in one another, i.e., for example, the tongue can engage in the notch in order to provide for a relative fixing and, in particular, also non-rotational fixing between cap and carrier-connection element in this way.

The object specified at the outset is accomplished in accordance with the invention, in a generic position sensor, in that the carrier and the connection element are rigidly connected to one another to form a carrier-connection element combination and a molding compound is arranged in a space between the carrier-connection element combination and an inner wall of the housing.

Such an inventive position sensor may be produced in a simple manner since the molding compound may be poured into the housing via a large opening space and the carrier-connection element combination may be aligned as a whole on account of the mechanically secure connection between carrier and connection element and, in particular, only a cap still has to be pushed on to close the position sensor at the rear end and the connection element does not have to be subsequently connected electrically to the carrier.

In this respect, the connection element is favorably a plug insert, with which a plug can be connected.

It is particularly advantageous when the connection element is soldered to the carrier since a rigid, mechanically secure connection can be produced as a result.

The housing is advantageously manufactured from metal. The housing has a high inherent stability as a result and protects the circuit from mechanical damage due to impacts and the like. In addition, the housing has a high stability with respect to environmental influences such as chemical substances, action on it due to heat, fluid and the like.

It is particularly advantageous when the housing is closed at a measuring end with a cup-shaped insert. As a result, the inventive position sensor may be produced in a simple manner. The cup-shaped insert extends, in particular, over more than one third of the length of the housing and so it is held securely in this housing and, in particular, can also be fixed well on the housing by means of molding compound.

The insert is advantageously manufactured from a plastic material. As a result, a measurement result is also not influenced, i.e. the insert cannot act as an inductive negative feedback with respect to a coil.

A sealing element is favorably formed on the insert for sealing between the insert and the inner wall of the housing. On the one hand, this seal prevents fluids such as coolant and machining waste such as metal chippings from being able to pass into the housing interior from outside and liquid molding compound from being able to exit from the housing interior out of the front end (measuring end) during the production of the inventive position sensor.

It is particularly advantageous when the insert is designed to be pushed into the housing so that it can be connected to the housing in a simple manner and, in addition, can be fixed on the housing additionally via molding compound.

In order to facilitate the production of the inventive position sensor, the insert is favorably designed such that it can be positioned on the housing in a force-locking manner. No additional, for example, clamping means need than be provided during the production in order to prevent the insert from detaching from the housing.

It is particularly advantageous when the housing is designed to be essentially rotationally symmetrical. The housing may then be produced in a simple manner.

The production is simplified further to a great extent when the housing interior has essentially the same cross section over the length of the housing. Tubular elements can then, in particular, be cut off to a corresponding length and no expensive special production is required for the inventive position sensor.

It is particularly advantageous when a cap is seated at a rear end of the position sensor facing away from the measuring end. This cap serves to close the rear end of the housing interior in relation to the surroundings. Connections of the connection element can also be guided through the cap in order to be able to supply the circuit of the position sensor with voltage with them and to be able to tap a measurement signal.

In this respect, it is favorable when the cap is of a plastic material. It is advantageous, in particular, when the cap is at least partially transparent. A light emitting diode can then be arranged, for example, on the carrier and this indicates, for example, the operational state of the position sensor. This light emitting diode can be read out via a transparent cap.

The production of the inventive position sensor may be simplified by the fact that the cap is pushed into the housing. The push-in length of a cap into the housing is, in particular, at least double the size of the inner diameter of the housing and is, for example, at least one third of the length of the housing so that the cap is held well in the housing. As a result, the cap, which is made of a plastic material, also effects a good insulation in relation to the housing and a high dielectric strength can be achieved.

The cap advantageously has a stop, due to which the insertion path into the housing is limited. As a result, a secure hold of the cap on the housing is provided and, on the other hand, it is also possible to avoid filling compound from rising above a specific level when the cap is pushed in.

It is particularly advantageous when the cap has an opening for the connection element. Connections such as contact pins of the connection element may be guided outwards through this opening. At the same time, the connection element may be aligned by this opening and, in particular, aligned in a centered manner and, again, the carrier-connection element combination may be aligned in order to ensure in this way, in particular, a quick and secure assembly. In particular, a strong shaking of the carrier-connection element combination in the molding compound poured in prior to its hardening, which would entail the risk of air pockets, may be avoided.

It is advantageous when the opening is designed such that the carrier-connection element combination can be fixed in the housing transversely to the longitudinal direction thereof by means of this opening.

It is particularly advantageous when the opening for the connection element has a smaller diameter than the housing. In this way, larger carriers can be pushed into the housing without the opening, which is required for a plug width, determining the diameter of the housing interior. As a result, the diameter of the connection element may be essentially decoupled from a width of the carrier-connection element combination which comes to rest in the housing interior.

The connection element is favorably provided with a fixing means and the cap with a fixing means adapted thereto and the fixing means can engage in one another. As a result, the carrier-connection element combination and the cap may be oriented relative to one another and, in particular, oriented non-rotationally relative to one another. As a result, the assembly of the device can be made easier.

In an advantageous variation of one embodiment, the cap is provided with an external thread. A clamping nut of a plug may be fixed on such an external thread and the plug may therefore be connected to the position sensor.

The cap is favorably provided with a holder element for the force-locking fixing in the housing. This holder element may serve at the same time to prevent the molding compound from flowing out of the housing between an inner wall of the housing and a cap wall when the cap is pressed into it.

### BRIEF DESCRIPTION OF THE DRAWINGS

The following description serves to explain the invention in greater detail in conjunction with the drawings. These show:

FIG. 1 a longitudinal section through one embodiment of an inventive position sensor in a schematic illustration and

FIG. 2 a detailed view of the area A according to FIG. 1.

### DETAILED DESCRIPTION OF EMBODIMENTS OF THE INVENTION

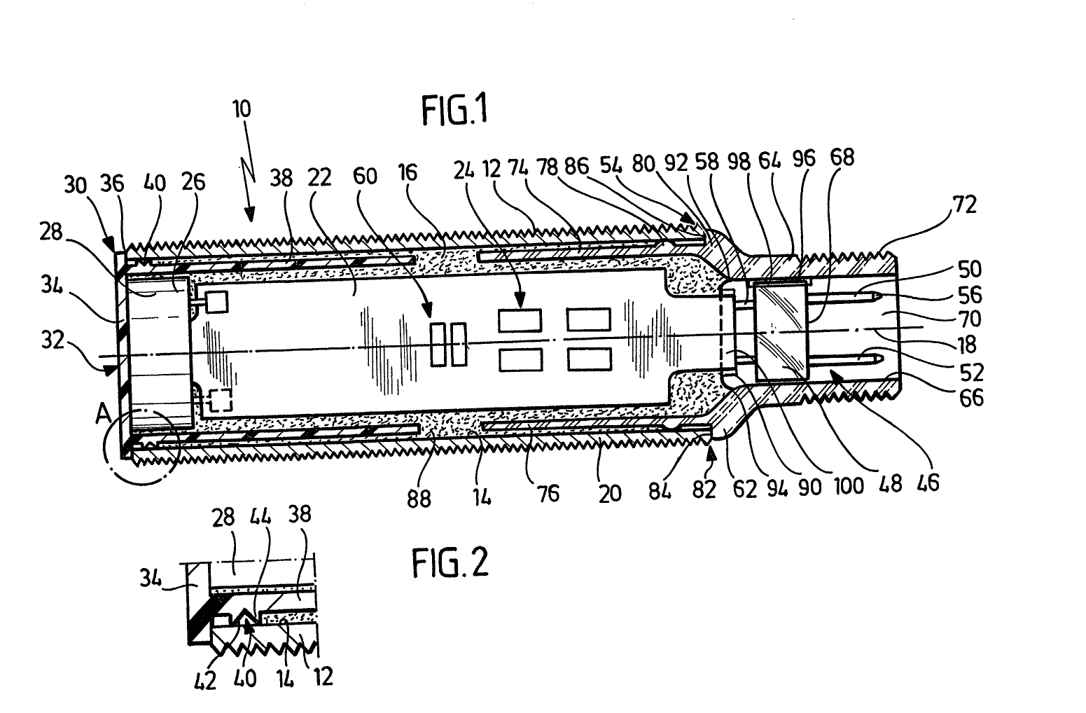

One embodiment of an inventive position sensor, which is designated in FIG. 1 as a whole as 10, comprises a housing manufactured, in particular, from a metallic material. This housing 12 has a cylindrical housing interior 16 which is formed by an inner wall 14 of the housing and thus has essentially the same cross section transversely to a longitudinal axis 18 of the housing 12 over the entire length of the housing interior 16. In a variation of one embodiment, the housing 12 is provided with an external thread 20 so that the inventive position sensor 10 can be fixed in a form-locking manner at its place of use, such as, for example, a machine tool.

A carrier or support 22 is arranged in the housing interior 16 and an electrical circuit 24 is arranged on this carrier.

The electrical circuit 24 comprises, in particular, a coil 26 which is provided with a pot core 28. The position sensor 10 is then an inductive proximity sensor, wherein an inductive negative feedback occurs due to a metallic object approaching the coil 26 and the corresponding changes in the electrical parameters can be registered.

The carrier 22 can, for example, be a printed circuit board, a ceramic substrate or also a flexible film, onto which the circuit components are embossed.

The coil 26 is positioned in the housing interior 16 in the vicinity of a front end 30 of the housing 12 so that this front end 30 forms a measuring end of the position sensor 10.

The front end of the housing interior 16 is closed by a cup-shaped insert 32 so that a closure element for closing the housing interior 16 in relation to the surroundings is formed by this insert 32.

The insert 32 is manufactured, in particular, from a plastic material so that the cover plate 34 does not influence the inductive coupling of an object of measurement to the coil 26.

The insert 32 comprises a disk-shaped cover plate 34 which abuts on the front end 30 of the housing 12 at an end face 36 of this housing 12. The diameter of the cover plate 34 is, in particular, somewhat smaller than the external diameter of the housing 12.

A cylindrical wall 38 is formed at right angles to the cover plate 34 and in one piece with it, wherein an external diameter of this wall 38 is slightly smaller than an internal diameter of the housing interior 16 so that the insert 32 can be pushed into the housing interior 16 from the front end 30. In this respect, it is provided, in particular, for the height of the wall 38 above the cover plate 34 to be at least one third of the length of the housing 12 and, in particular, to be approximately half the length of the housing so that the wall 38 projects into the housing interior 16 over a larger area.

As shown in greater detail in FIG. 2, the wall 38 is provided in the vicinity of the cover plate 34 with a circular sealing element 40 which is formed on it in one piece and is located between the insert and the housing inner wall 14 when the insert 32 is pushed in. In the embodiment shown, the sealing element is formed by two oppositely located sealing lips 42 and 44 which are triangular in cross section, namely in the shape of an essentially right-angled triangle. The right angle is formed, in the case of the sealing lip 42, between the wall 38 and a side facing the cover plate and, in the case of the sealing lip 44, between the wall 38 and the side facing away from the cover plate 34. The sides of the sealing lips 42 and 44 arranged at an incline in relation to the wall 38 abut on one another between the corresponding, right-angled sides.

As a result of the sealing element 40, a liquid molding compound is, on the one hand, prevented from entering the surroundings from the housing interior 16 and a fluid from the surroundings is prevented from entering the housing interior 16. In addition, the sealing element 40 contributes to the insert 32 being held on the housing 12 in a force-locking manner after its insertion into the housing interior 16, whereby the production of the inventive position sensor 10 is made easier.

At an end of the carrier 22 facing away from the end, at which the coil 26 is arranged, the carrier is rigidly connected to a connection element 46, which is, in particular, a plug insert, such that the connection is mechanically secure and is flexible essentially in no direction. The connection element 46 comprises a contact carrier 48, into which contact pins 50 are cast. Four contact pins are, for example, provided.

Such a contact pin has an essentially straight part 52 which is oriented away from a rear end 54 of the housing 12 facing away from the front end 30 and is aligned, in particular, essentially parallel to the longitudinal axis 18. Such a straight part 52 of a contact pin 50 is chamfered at an end section 56 in order to facilitate the introduction of a plug.

A contact pin 50 is guided and, in particular, bent due to the contact carrier 48 such that it can be rigidly connected at a connection part 58 to the carrier 22. The connection part 58 is soldered to the carrier 22 for this purpose.

A supply current may be supplied to the circuit 24 via the electrical connection element and, in particular, via contact pins 50 and a sensor signal tapped for further processing.

As a result of the soldering of the electrical connection element 46 via the contact pins 50 to the carrier 22, a carrier-contact element combination 60 is formed which can be positioned as a unit during the production of the inventive position sensor 10.

A cap 62 is pushed into the housing interior 16 at the rear end 54 to close the housing 12 in relation to the surroundings. The cap 62 comprises for this purpose a first section 64 which is of an essentially cylindrical design and provided with a cylindrical opening 66, in which the contact carrier 48 and the straight parts 52 of the contact pins 50 are arranged. The diameter of the opening 66 corresponds essentially to the diameter of the contact carrier 48. A receiving space 70 for a plug for the connection to the contact pins 50 is formed in the opening 66 from the end face 68 of the contact carrier 48 facing away from the rear end 54 towards the surroundings. Furthermore, the first section 64 is provided with an external thread 72 so that a plug can be fixed on the cap 62, for example, by means of a clamping nut.

The cap 62 further comprises a second section 74 which is formed by a cylindrical wall 76 and is pushed into the housing interior 16. The wall 76 is provided with a circular, projecting annular collar 78 formed on it in one piece; this annular collar 78 is arranged such that it is positioned somewhat beneath the rear end 54 of the housing 12 when the second section 74 is pushed in. The cap 62 may be held on the housing 12 in a force-locking manner as a result of the annular collar 78. At the same time, care is taken that, when the external diameter of the wall 76 is somewhat smaller than the internal diameter of the housing interior 16, the cap may be pushed into the housing interior 16 in a simple manner.

The second section 74 is adapted to the housing diameter and the first section 64 to a plug diameter. Normally, a plug diameter is smaller than a housing diameter and therefore the first section 64 has a smaller diameter than the second section 74.

A third section 80 of the cap 62 provides the transition between the first section 64 and the second section 74. For this purpose, this third section is designed in the shape of a truncated cone not only in relation to an external surface but also an internal surface. At the transition 82 between the third section 80 into the second section 74 a nose 84 in the shape of a circular ring is formed and the cap 62 can be abutted on an end face 86 at the rear end 54 by means of this nose when the cap 62 is pushed into the housing interior 16 with the second section 74.

A free space in the housing interior 16, which is formed around the carrier 22 with the circuit arranged thereon, around the wall 38 of the insert 32 and the wall 76 of the cap 62, is filled with a molding compound 88 solid after hardening, such as, in particular, a casting resin. As a result, the electrical circuit 24 is protected since no fluids can penetrate to the electronic components. On the other hand, as a result of the molding compound the insert 32 is held on the housing 12 and also the cap 62 is held on the housing 12. This can be aided by the fact that the walls 38 and 76 are provided, in particular, facing the carrier 22 with recesses or the like for improving the coupling of the molding compound 88 (not shown in the drawings).

During the production of the inventive position sensor 10, the molding compound is poured in up to a specific level. During the insertion of the carrier-connection element combination 60 and/or during insertion of the cap 62 the molding compound which is still fluid rises up to a level defined by the amount of the liquid molding compound poured in. The filling amount is selected such that the molding compound 88 essentially covers the carrier 22 completely but leaves a space 90 free between the carrier 22 and the contact carrier 48, in which the connection parts 58 of the contact pins 50 are arranged. As a result, a breakdown at the connection parts 58 of the contact pins can be avoided which could result if a molding compound sheathing were not completely continuous.

One end 92 of the molding compound sheathing is then located essentially in the area of the third section 80 of the cap 62 or in the initial area of the opening 66 in the first section 64 of the cap 62. Towards the cap 62, the end 92 of the molding compound sheathing has a meniscus-like elevation 94.

During the insertion of a cap 62, due to which the liquid molding compound is displaced in the direction of the rear end 54, the provision of such a space 90 also serves to prevent the molding compound from hindering any abutment of the nose 84 on the end face 86 because too great an amount of liquid molding compound has erroneously been poured in.

The space 90 thereby reduces the precision requirements in relation to the control of the molding compounds to be poured in.

A shrinkage band 100 is arranged around the carrier 22 at the end of the carrier 22, in particular, lying at least partially in the space 90 in order to increase the dielectric strength and thus increase the safety class.

The cap 62 is manufactured from a plastic material and, in particular, from a transparent plastic material. As a result, a light emitting diode arranged at the end of the carrier 22, which serves, for example, to monitor the functioning of the inventive position sensor 10, may be observed from the surroundings.

The cap 62 protrudes into the housing interior 16 with a length at least twice as great as the internal diameter thereof. As a result, an insulation is provided for in addition to the insulating property of the molding compound in order to improve the safety class of the position sensor in this way.

The position sensor is manufactured in accordance with the invention as follows:

The carrier 22 is rigidly connected to the connection element 46 to form the carrier-connection element combination 60. With a front end (measuring end) 30 closed by means of the insert 32, which is pushed into the housing interior 16, the carrier-connection element combination 60 is inserted into the housing interior 16, namely such that the pot core 28 of the coil 26 abuts on the surface of the cover plate facing the housing interior 16. For this purpose, the housing 12 is, in particular, located on the cover plate 34 so that the longitudinal axis 18 of the housing 12 is oriented essentially parallel to the direction of gravity.

A liquid molding compound and, in particular, a casting resin is then poured into the housing interior 16, namely up to a specific level in order to be able to form the space 90 between the end 92 of the molding compound sheathing and the contact carrier 48. For this purpose, the amount of the liquid molding compound poured in is advantageously controlled as a function of the volume of the housing interior 16 and the size of the carrier 22.

The molding compound can also penetrate the area between the insert 32 and the housing inner wall 14 and thus fix it (in addition) on the housing 12. The same applies for the cap 62.

In this respect, it is favorable when the carrier 22 is leaned against a housing inner wall 14 during the filling in order to thus achieve a greater filling opening for filling the housing 12.

After filling with the liquid molding compound, the carrier-connection element combination 60 is aligned in relation to the longitudinal direction 18 prior to hardening of the molding compound such that the contact carrier 48 of the connection element 46 is essentially collinear to the longitudinal axis 18. The second section 74 is then pushed into the molding compound, which is still fluid, in the housing interior 16 to connect the cap 62 to the housing 12, wherein an alignment takes place between the opening 66 of the cap 62 and the contact carrier 48.

To facilitate this alignment and/or to improve the coupling between the cap 62 and the contact carrier 48 it may be provided for the contact carrier 48 to be provided with a notch 96 parallel to the longitudinal direction 18 and for the cap 62 to be provided with a bar 98 in the opening 66 which is adapted to the notch 96. This bar 98 can then engage in the notch 96 in order to thus obtain a form-locking coupling between the cap 62 and the connection element 46.

After insertion of the cap 62 as far as abutment of the nose 84 on the end face 86, the hardening of the molding compound 88 is awaited. The inventive position sensor 10 is then completely finished.

In an alternative process, the carrier-connection element combination 60 is not, in contrast to the process described above, pushed into the housing interior 16 first but rather this interior, with an insert 32 inserted, is first filled with a liquid molding compound and then the carrier-connection element combination 60 is pushed from the rear end 54 into the housing interior 16 with the molding compound located therein, which is not yet hardened, until the pot core 28 abuts against the cover plate 34. Subsequently, the cap 62 is then placed on the inserted carrier-connection element combination 60 as long as the molding compound is not yet hardened.

Alternatively to the subsequent placement of the cap 62, this can also be placed on the carrier-connection element combination 60 first of all prior to insertion of the carrier-connection element combination 60 into the filled housing 12 and the unit consisting of carrier-connection element combination 60 and positioned cap 62 is then inserted into the housing interior 16.

As a result of the filling with molding compound from the rear end 54 such that a homogeneous distribution of the molding compound is achieved and the space 92 is formed in a controlled manner, the centering of the carrier-connection element combination 60 by means of the cap 62 and the insulating, inserted second section 74 of the cap 62, a high dielectric strength is achieved between the housing 12 and the circuit 24 and so the inventive position sensor 10 has a high safety class.

The present disclosure relates to the subject matter disclosed in German Application No. 100 13 218.9 of Mar. 17, 2000, the entire specification of which is incorporated herein by reference.

1. Process for the production of a position sensor comprising a housing, an electrical circuit arranged on a carrier being seated in its housing interior, comprising the steps:
the carrier is connected to an electrical connection element to form a carrier-connection element combination;
the carrier-connection element combination is introduced into the housing closed at a measuring end from a rear end located opposite the measuring end;
the space around the carrier-connection element combination in the interior of the housing is filled with a molding compound up to a specific level and
a cap is connected to the rear end of the housing, the connections of the connection element being guided through said cap.

2. Process as defined in claim 1, characterized in that the carrier-connection element combination is arranged in the housing at an angle to a longitudinal direction when molding compound is poured in.

3. Process as defined in claim 2, characterized in that the carrier-connection element combination is leaned against an inner wall of the housing when molding compound is poured in.

4. Process for the production of a position sensor with a housing, an electronic circuit arranged on a carrier being seated in its housing interior, comprising the steps:
the carrier is connected to an electrical connection element to form a carrier-connection element combination;
a molding compound is poured into the housing interior of the housing closed at a measuring end up to a specific level;
the carrier-connection element combination is pushed into the housing interior into the molding compound and
a cap is connected to the rear end of the housing, the connections of the connection element being guided through said cap.

5. Process as defined in claim 1, characterized in that the connection element is rigidly connected to the carrier.

6. Process as defined in claim 5, characterized in that a plurality of contact pins of the connection element are connected to the carrier.

7. Process as defined in claim 5, characterized in that the connection element is soldered to the carrier.

8. Process as defined in claim 1, characterized in that a cup-shaped insert is provided for closing the housing at the measuring end, said insert being pushed into the housing in the direction of the rear end from the measuring end.

9. Process as defined in claim 8, characterized in that the insert is held on the housing in a force-locking manner after its insertion.

10. Process as defined in claim 1, characterized in that the carrier-connection element combination is placed onto a closure element forming the closed measuring end.

11. Process as defined in claim 1, characterized in that the housing is oriented in its longitudinal direction essentially parallel to the direction of gravity during the introduction of the carrier-connection element combination and/or during the filling with the molding compound.

12. Process as defined in claim 1, characterized in that the amount of molding compound poured into the housing is controlled.

13. Process as defined in claim 1, characterized in that during the connection of the cap with the housing the carrier-connection element combination is aligned in longitudinal direction of the housing.

14. Process as defined in claim 1, characterized in that during the connection of the cap with the housing the carrier-connection element combination is aligned essentially collinear to the longitudinal axis of the housing.

15. Process as defined in claim 1, characterized in that the cap is pushed into the housing.

16. Process as defined in claim 15, characterized in that the cap is pushed into the housing as far as a stop defined on the cap.

17. Process as defined in claim 15, characterized in that the cap is pushed into the housing prior to hardening of the molding compound.

18. Process as defined in claim 4, characterized in that the cap is positioned on the carrier-connection element combination before the carrier-connection element combination is pushed into the housing interior.

19. Process as defined in claim 18, characterized in that the carrier-connection element combination is pushed into the housing with the cap positioned.

20. Process as defined in claim 1, characterized in that the cap is provided with a fixing means and the connection element with a fixing means adapted thereto.

21. Process as defined in claim 20, characterized in that during the connection of the cap with the housing the cap and the carrier-connection element combination are oriented relative to one another such that the respective fixing means can engage on one another.

22. Position sensor comprising a housing (12) for accommodating an electrical circuit (24) arranged on a carrier (22) in a housing interior (16) and an electrical connection element (46), characterized in that the carrier (22) and the connection element (46) are rigidly connected to one another to form a carrier-connection element combination (60) and a molding compound (88) is arranged in a space between the carrier-connection element combination and an inner wall (14) of the housing.

23. Position sensor as defined in claim 22, characterized in that the connection element (46) is a plug insert.

24. Position sensor as defined in claim 22, characterized in that the connection element (46) is soldered to the carrier (22).

25. Position sensor as defined in claim 22, characterized in that the housing (12) is manufactured from metal.

26. Position sensor as defined in claim 22, characterized in that the housing (12) is closed at a measuring end (30) with a cup-shaped insert (32).

27. Position sensor as defined in claim 26, characterized in that the insert (32) is manufactured from a plastic material.

28. Position sensor as defined in claim 26, characterized in that a sealing element (40) is formed on the insert (32) for sealing between the insert (32) and the inner wall (14) of the housing.

29. Position sensor as defined in claim 26, characterized in that the insert (32) is designed to be pushed into the housing (12).

30. Position sensor as defined in claim 29, characterized in that the insert is designed such that it is positionable on the housing (12) in a force-locking manner.

31. Position sensor as defined in claim 22, characterized in that the housing (12) is designed to be essentially rotationally symmetrical.

32. Position sensor as defined in claim 22, characterized in that the housing interior (16) has essentially the same cross section over the length of the housing (12).

33. Position sensor as defined in claim 22, characterized in that a cap (62) is seated at a rear end (54) of the position sensor (10) facing away from the measuring end (30).

34. Position sensor as defined in claim 33, characterized in that the cap (62) is of a plastic material.

35. Position sensor as defined in claim 33, characterized in that the cap (62) is at least partially transparent.

36. Position sensor as defined in claim 33, characterized in that the cap (62) is pushed into the housing (12).

37. Position sensor as defined in claim 36, characterized in that the cap (62) has a stop (84), the insertion into the housing (12) being limited by said stop.

38. Position sensor as defined in claim 33, characterized in that the cap has an opening (66) for the connection element (46).

39. Position sensor as defined in claim 38, characterized in that the opening is designed such that the carrier-connection element combination (60) is adapted to be fixed in the housing (12) transversely to the longitudinal direction (18) thereof by means of said opening.

40. Position sensor as defined in claim 38, characterized in that the opening (66) for the connection element (46) has a smaller diameter than the housing (12).

41. Position sensor as defined in claim 33, characterized in that the connection element (46) is provided with a fixing means (96) and the cap (62) with a fixing means (98) adapted thereto and the fixing means (96, 98) are adapted to engage in one another.

42. Position sensor as defined in claim 33, characterized in that the cap (62) is provided with an external thread (72).

43. Process as defined in claim 4, characterized in that the connection element is rigidly connected to the carrier.

44. Process as defined in claim 43, characterized in that a plurality of contact pins of the connection element are connected to the carrier.

45. Process as defined in claim 43, characterized in that the connection element is soldered to the carrier.

46. Process as defined in claim 4, characterized in that a cup-shaped insert is provided for closing the housing at the measuring end, said insert being pushed into the housing in the direction of the rear end from the measuring end.

47. Process as defined in claim 46, characterized in that the insert is held on the housing in a force-locking manner after its insertion.

48. Process as defined in claim 4, characterized in that the carrier-connection element combination is placed onto a closure element forming the closed measuring end.

49. Process as defined in claim 4, characterized in that the housing is oriented in its longitudinal direction essentially parallel to the direction of gravity during the introduction of the carrier-connection element combination and/or during the filling with the molding compound.

50. Process as defined in claim 4, characterized in that the amount of molding compound poured into the housing is controlled.

51. Process as defined in claim 4, characterized in that during the connection of the cap with the housing the carrier-connection element combination is aligned in longitudinal direction of the housing.

52. Process as defined in claim 4, characterized in that during the connection of the cap with the housing the carrier-connection element combination is aligned essentially collinear to the longitudinal axis of the housing.

53. Process as defined in claim 4, characterized in that the cap is pushed into the housing.

54. Process as defined in claim 53, characterized in that the cap is pushed into the housing as far as a stop defined on the cap.

55. Process as defined in claim 53, characterized in that the cap is pushed into the housing prior to hardening of the molding compound.

56. Process as defined in claim 4, characterized in that the cap is provided with a fixing means and the connection element with a fixing means adapted thereto.

57. Process as defined in claim 56, characterized in that during the connection of the cap with the housing the cap and the carrier-connection element combination are oriented relative to one another such that the respective fixing means can engage on one another.
